(19) United States
(12) Patent Application Publication
(10) Pub. No.: US 2007/0071157 A1
(43) Pub. Date: Mar. 29, 2007

(54) CLOCK RECOVERY CIRCUIT AND CLOCK RECOVERY METHOD

(76) Inventor: Chao-Hsin Lu, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/469,878

(22) Filed: Sep. 4, 2006

(30) Foreign Application Priority Data
Sep. 23, 2005 (TW) 094133201

(51) Int. Cl. H03D 3/24

(52) U.S. Cl. 375/376

(57) ABSTRACT

A clock recovery circuit for generating an output clock corresponding to an input signal is disclosed. The clock recovery circuit includes: a phase detection unit for receiving the input signal and the output clock and generating a phase error signal according to the input signal and the output clock; a serial-to-parallel converting unit coupled to the phase detection unit for converting the serial phase error signal to a plurality of parallel phase error signals; a plurality of charging/discharging units coupled to the serial-to-parallel converting unit for generating an adjustment signal according to the parallel phase error signals; and an oscillator for generating the output clock according to the adjustment signal.

### BACKGROUND OF THE INVENTION

1. Field of the Invention

The present invention relates to a method and apparatus of clock recovery, and more particularly, to a method and apparatus using a serial to parallel converting unit to convert a serial phase error signal into a plurality of parallel phase error signals.

2. Description of the Prior Art

As is well known in the IC design industry, a clock recovery circuit is commonly used in optical communications. Please refer to FIG. 1. FIG. 1 is a functional block diagram of a clock recovery circuit 100 according to the prior art. The clock recovery circuit 100 comprises a phase detection unit 110, a charging/discharging unit 120, a loop filter 130, and a controllable oscillator 140. The phase detection unit 110 samples an input signal D_{A} according to a clock recovery signal CLKₒᵤₜ, which is fed back to the phase detection unit by the controllable oscillator 140 (this may be a voltage-control oscillator or a current-control oscillator), and generates a phase error signal E_{A}. Next, the charging/discharging unit 120 outputs a tuning signal I_{A} according to the phase error signal E_{A}, and the loop filter 130 then filters the tuning signal I_{A} to output a control signal C_{A}, for driving the controllable oscillator 140 to generate the clock recovery signal CLKₒᵤₜ. The clock recovery signal CLKₒᵤₜ will then be fed back to the phase detection unit 110 again.

U.S. Pat. No. 6,442,225 further discloses another kind of clock recovery circuit. For more details, please refer to this patent.

### SUMMARY OF THE INVENTION

One objective of the present invention is to provide a method and apparatus of clock recovery using a serial to parallel converting unit to convert a serial phase error signal into a plurality of parallel phase error signals, and generate a clock signal.

According to an embodiment of the present invention, a clock recovery circuit for generating an output clock signal with respect to an input signal is disclosed. The clock recovery circuit is for generating an output clock corresponding to an input signal. The clock recovery circuit includes: a phase detection unit for receiving the input signal and the output clock and generating a serial phase error signal according to the input signal and the output clock; a serial-to-parallel converting unit coupled to the phase detection unit for converting the serial phase error signal into a plurality of parallel phase error signals; a plurality of charging/discharging units coupled to the serial-to-parallel converting unit for generating an adjustment signal according to the parallel phase error signals; and an oscillator for generating the output clock according to the adjustment signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a functional block diagram of a clock recovery circuit in the prior art.

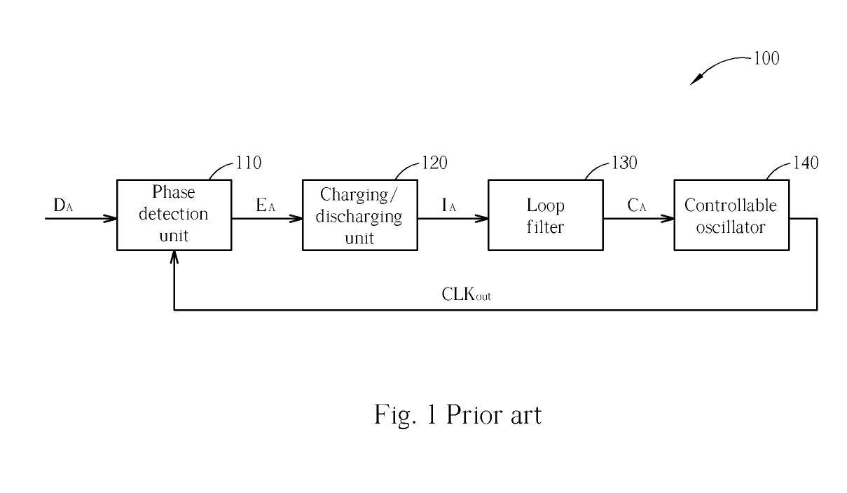

FIG. 2 is a functional block diagram of an embodiment of a clock recovery circuit according to the present invention.

FIG. 3 is a flow chart of the clock recovery circuit in FIG. 2 when generating an output clock signal to lock an input signal.

### DETAILED DESCRIPTION

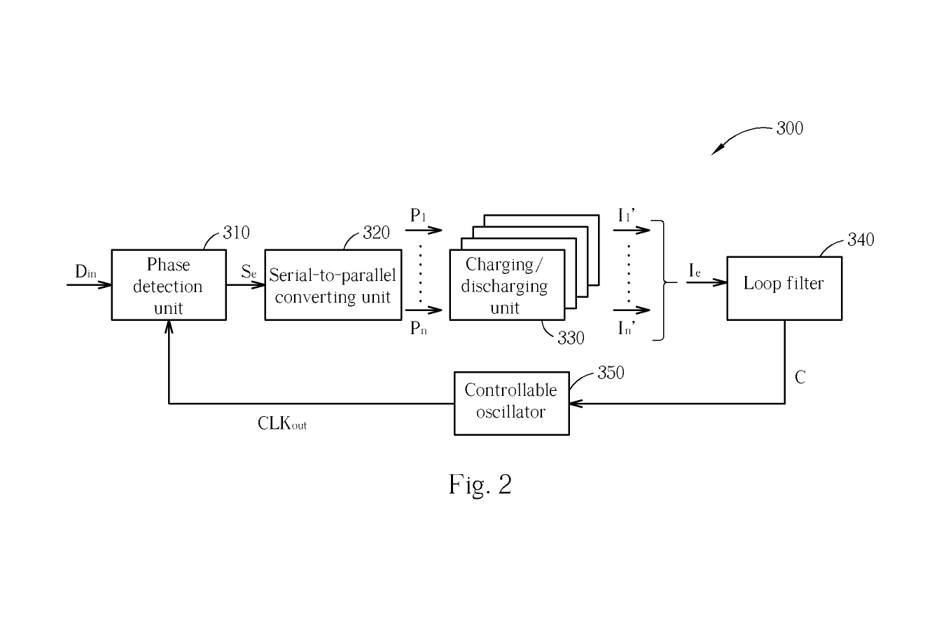

Please refer to FIG. 2. FIG. 2 is a functional block diagram of an embodiment of a clock recovery circuit 300 of the present invention. The clock recovery circuit 300 comprises a phase detection unit 310, a serial-to-parallel converting unit 320, a plurality of charging/discharging units 330, a loop filter 340, and a controllable oscillator 350. In this embodiment, the phase detection unit 310 can be any linear or binary phase detector. Moreover, the serial-to-parallel converting unit 320 utilizes a demultiplexer for carrying out a serial to parallel conversion according to an output clock signal CLKₒᵤₜ.

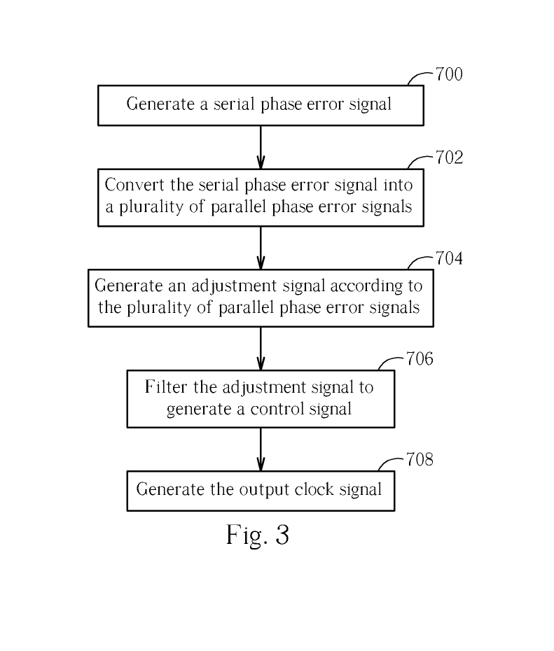

Please refer to FIG. 3 and FIG. 2 together. FIG. 3 is a flow chart of the clock recovery circuit in FIG. 2 when generating an output clock signal to lock an input signal. Generating the clock signal CLKₒᵤₜ to lock a input signal Dᵢₙ comprises the following steps:

Step 700: Generate a serial phase error signal Se according to a phase difference between the input signal Din and output clock signal CLKout;

Step 702: Convert the serial phase error signal Se into a plurality of parallel phase error signals P1˜Pn;

Step 704: Generate an adjustment signal Ie according to the plurality of parallel phase error signals P1˜Pn, wherein the plurality of parallel phase error signals P1˜Pn have frequencies lower than the frequency of the serial phase error signal Se.

Step 706: Filter the adjustment signal Ie to generate a control signal C; and

Step 708: Generate the output clock signal CLKout according to the control signal C.

In this embodiment, output signal Dᵢₙ can be a coded random signal with a range from 2⁷-1 to 2³¹-1, in other words, a non-return to zero (NRZ) signal, which is usually utilized in very high speed optical communications. The phase detection unit 310 takes the output clock CLKₒᵤₜ as a sample clock for sampling the input signal Dᵢₙ, and converting the sampled input signal Dᵢₙ into a serial phase error signal Sₑ (Step 700), wherein the serial phase error signal Sₑ represents a phase difference between the input signal Dᵢₙ and the output clock signal CLKₒᵤₜ. The serial-to-parallel converting unit 320 then converts the serial phase error signal Sₑ into a plurality of parallel phase error signals P₁˜Pₙ (Step 702). Please note that, in this embodiment, the number n of the plurality of parallel phase error signals depends on the operating speed a system can stand. For example, when designing the clock recovery circuit 300 to be operated at 2 Gbps, and if the charging/discharging unit 330 operates at 700˜800 Mhz, the serial phase error signal Sₑ is converted into “four” parallel phase error signals P₁˜P₄ under considerations of manufacturing process and temperature variations. Since the frequencies of the parallel phase error signals P₁˜P₄ (corresponding to 700˜800 Mhz) are lower than the frequency of the serial phase error signal Sₑ (corresponding to 2 Ghz), designing the charging/discharging unit 330 becomes significantly more simple.

After being processed by the serial-to-parallel converting unit 320, the serial phase error signal Sₑ is converted to the plurality of parallel phase error signals P₁˜Pₙ. Therefore the plurality of charging/discharging units 330 are required to separately receive the plurality of parallel phase error signals P₁˜Pₙ in order to generate an adjustment signal Iₑ comprising a plurality of charging/discharging signals I₁′˜Iₙ′ to be input to the loop filter 340 (Step 704). In this embodiment, the loop filter 340 is a kind of low-pass filter used for filtering the adjustment signal Iₑ to generate the control signal C (Step 706). The control signal C is further fed back to the controllable oscillator 350 (e.g. a voltage-control oscillator or a current-control oscillator), to drive the controllable oscillator 350 to output the needed output clock signal CLKₒᵤₜ (Step 708). Since the implementations of the loop filter 340 such as the loop filter disclosed by U.S. Pat. No. 6,442,225 and the controllable oscillator 350 such as a VCO or an ICO are well known in the art, unnecessary details are not provided in this disclosure.

A clock recovery circuit in this embodiment applies a serial-to-parallel converting unit to lower the operating frequency of the plurality of charging/discharging units. Moreover, this circuit also enables a controllable oscillator to operate at a high frequency and generate a needed clock recovery signal. The present invention thus has the advantages of both low clock jitter, and simplicity of designing a charging/discharging unit.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A clock recovery circuit for generating an output clock corresponding to an input signal, the clock recovery circuit comprising:
a phase detection unit, for receiving the input signal and the output clock and generating a serial phase error signal according to the input signal and the output clock;
a serial-to-parallel converting unit, coupled to the phase detection unit, for converting the serial phase error signal into a plurality of parallel phase error signals;
a plurality of charging/discharging units, coupled to the serial-to-parallel converting unit, for generating an adjustment signal according to the parallel phase error signals; and
an oscillator for generating the output clock according to the adjustment signal.

2. The clock recovery circuit of claim 1, wherein the adjustment signal comprises a plurality of charging/discharging signals.

3. The clock recovery circuit of claim 2 further comprising:
a filter, coupled between the charging/discharging units and the oscillator, for generating a control signal according to the plurality of charging/discharging signals such that the oscillator generates the output clock according to the control signal.

4. The clock recovery circuit of claim 1, wherein at least one of the charging/discharging units operates according to a first frequency, and the first frequency is lower than a frequency of the output clock.

5. The clock recovery circuit of claim 1, wherein the input signal is a non-periodic signal.

6. The clock recovery circuit of claim 1, wherein the serial-to-parallel converting unit is a demultiplexer.

7. The clock recovery circuit of claim 1, wherein the serial-to-parallel converting unit is further coupled to the oscillator, and operates according to the output clock.

8. A method of clock recovery for generating an output clock corresponding to an input signal, the method comprising:
detecting a phase error between the input signal and the output clock and generating a serial phase error signal according to the input signal and the output clock;
converting the serial phase error signal to a plurality of parallel phase error signals;
generating an adjustment signal according to the parallel phase error signals; and
generating the output clock according to the adjustment signal.

9. The method of claim 8, wherein the adjustment signal comprises a plurality of charging/discharging signals.

10. The method of claim 9 further comprising:
generating a control signal according to the plurality of charging/discharging signals such that the output clock is generated according to the control signal.

11. The method of claim 8, wherein the input signal is a non-periodic signal.

12. The method of claim 8, wherein the step of converting the serial phase error signal into a plurality of parallel phase error signals is executed by demultiplexing the serial phase error signal.

13. The method of claim 8, wherein the step of converting the serial phase error signal to a plurality of parallel phase error signals is executed according to the output clock.

14. The method of claim 8, wherein the step of generating the adjustment signal is executed according to a frequency lower than the frequency of the output clock.
